(19) United States
(12) Patent Application Publication
(10) Pub. No.: US 2025/0299966 A1
(43) Pub. Date: Sep. 25, 2025

(54) METHOD FOR FORMING HOLES AND METHOD FOR FABRICATING SEMICONDUCTOR DEVICE USING THE SAME

(71) Applicant: SK hynix Inc., Gyeonggi-do (KR)

(72) Inventor: Joon Seuk LEE, Gyeonggi-do (KR)

(21) Appl. No.: 18/823,688

(22) Filed: Sep. 4, 2024

(30) Foreign Application Priority Data
Mar. 21, 2024 (KR) 10-2024-0038960

(51) Int. Cl. H01L 21/311; H01L 21/033

(52) U.S. Cl. CPC H01L 21/31144; H01L 21/0332; H01L 21/0337

(57) ABSTRACT

A method for forming a hole pattern includes forming a hard mask layer over an etch target layer; forming a first sacrificial pattern including a preliminary hole pattern over the hard mask layer; forming a first sacrificial spacer on an inner wall of the first sacrificial pattern; forming a second sacrificial pattern to gap-fill between the first sacrificial spacers; removing the first sacrificial pattern; forming second sacrificial spacers on both sidewalls of a pillar pattern which is formed of the first sacrificial spacer and the second sacrificial pattern; removing the second sacrificial pattern; forming a hard mask pattern by using the first and second sacrificial spacers as an etch barrier and etching the hard mask layer; and forming an etch pattern including a hole pattern by using the hard mask pattern as an etch barrier and etching the etch target layer.

### CROSS-REFERENCE TO RELATED APPLICATIONS

The present application claims priority under 35 U.S.C 119(a) to Korean Patent Application No. 10-2024-0038960, filed on Mar. 21, 2024, which is incorporated herein by reference in its entirety.

### BACKGROUND

### 1. Field

Various embodiments of the present invention relate generally to semiconductor technology and, and more particularly, to a method for forming a fine hole pattern of a semiconductor device.

### 2. Description of the Related Art

As semiconductor devices become smaller and more highly integrated, methods for forming fine patterns are being developed. For the existing photolithography process, new exposure equipment is being developed to form the fine patterns, but there are limitations in forming the patterns with a line width below a predetermined critical dimension.

It is possible to form a small pitch by introducing EUV (Extreme Ultraviolet), but there are concerns in that the EUV equipment is expensive and the smaller a pattern is, the poorer the profile becomes. In particular, in the case of forming fine hole patterns, the difficulty of multi-patterning technology using DUV (Deep Ultraviolet) more than two times is very high, so there is a limitation in replacing EUV with DUV.

### SUMMARY

Embodiments of the present invention are directed to a method for forming a hole pattern that may decrease process difficulty and secure process margin, and a method for fabricating a semiconductor device using the same.

In accordance with an embodiment of the present invention, a method for forming a hole pattern includes forming a hard mask layer over an etch target layer; forming a first sacrificial pattern including a preliminary hole pattern over the hard mask layer; forming a first sacrificial spacer on an inner wall of the first sacrificial pattern; forming a second sacrificial pattern to gap-fill between the first sacrificial spacers; removing the first sacrificial pattern; forming second sacrificial spacers on both sidewalls of a pillar pattern which is formed of the first sacrificial spacer and the second sacrificial pattern; removing the second sacrificial pattern; forming a hard mask pattern by using the first and second sacrificial spacers as an etch barrier and etching the hard mask layer; and forming an etch pattern including a hole pattern by using the hard mask pattern as an etch barrier and etching the etch target layer.

In accordance with another embodiment of the present invention, a method for fabricating a semiconductor device includes forming a mold layer and a supporter layer that include storage node holes over a substrate; forming a lower electrode gap-filling the storage node holes and coupled to the substrate; forming a hard mask layer over the lower electrode and the supporter layer; forming a first sacrificial pattern including a preliminary hole pattern over the hard mask layer; forming a first sacrificial spacer on an inner wall of the first sacrificial pattern; forming a second sacrificial pattern to gap-fill between the first sacrificial spacers; removing the first sacrificial pattern; forming second sacrificial spacers on both sidewalls of a pillar pattern which is formed of the first sacrificial spacer and the second sacrificial pattern; removing the second sacrificial pattern; forming a hard mask pattern including a hole pattern by using the first and second sacrificial spacers as an etch barrier and etching the hard mask layer; and forming a supporter including a supporter hole by using the hard mask pattern as an etch barrier and etching the supporter layer.

These and other features and advantages of the present invention will become better understood by those having ordinary skill in the art from the following detailed description and the accompanying drawings.

### BRIEF DESCRIPTION OF THE DRAWINGS

FIGS. 1A, 2A, 3A, 4A, 5A, 6A, 7A, 8A, 9A, 10A, 11A and 12A are plan views illustrating a method for forming a hole pattern in accordance with an embodiment of the present invention.

FIGS. 1B, 2B, 3B, 4B, 5B, 6B, 7B, 8B, 9B, 10B, 11B and 12B are cross-sectional views taken along a line A-A′ shown in FIGS. 1A, 2A, 3A, 4A, 5A, 6A, 7A, 8A, 9A, 10A, 11A and 12A, respectively.

FIGS. 1C, 2C, 3C, 4C, 5C, 6C, 7C, 8C, 9C, 10C, 11C and 12C are cross-sectional views taken along a line B-B′ shown in FIGS. 1A, 2A, 3A, 4A, 5A, 6A, 7A, 8A, 9A, 10A, 11A and 12A, respectively.

FIGS. 13 to 19 are cross-sectional views illustrating a method for fabricating a semiconductor device in accordance with an embodiment of the present invention.

### DETAILED DESCRIPTION

Various example embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Typically, in the case of forming fine hole patterns such as contact holes, a mesh patterning method or two or more mask processes may be applied to form a small pitch. Here, the mesh patterning method may refer to a process of etching a lower layer by crossing a vertical line and a horizontal line that are orthogonal to each other, or crossing diagonal lines that are orthogonal to each other. However, as a pitch becomes smaller, it is required to additionally apply a spacer patterning method for the mesh patterning, which may cause imbalance of line width or pitch, resulting in poor uniformity between hole patterns. This complication may also occur in multiple patterning in which two or more mask processes are applied.

Therefore, according to an embodiment of the present invention, in order to simultaneously satisfy productivity and quality improvement, a patterning process that may form a pattern with a sufficient margin by using a sheet of a DUV (Deep Ultraviolet) mask and reduce pitch scaling while ensuring uniformity may be provided.

According to an embodiment of the present invention described below, a hole pattern may be formed as large as possible in order to maximize the process margin, and then the finally required hole pattern size may be reduced through a spacer deposition process, and a hole pattern array of a small pitch may be finally formed by filling the space between the initially formed hole patterns by additionally depositing spacers, and forming a hole pattern in the empty space at the central point between the hole patterns that are not completely filled through an etching process.

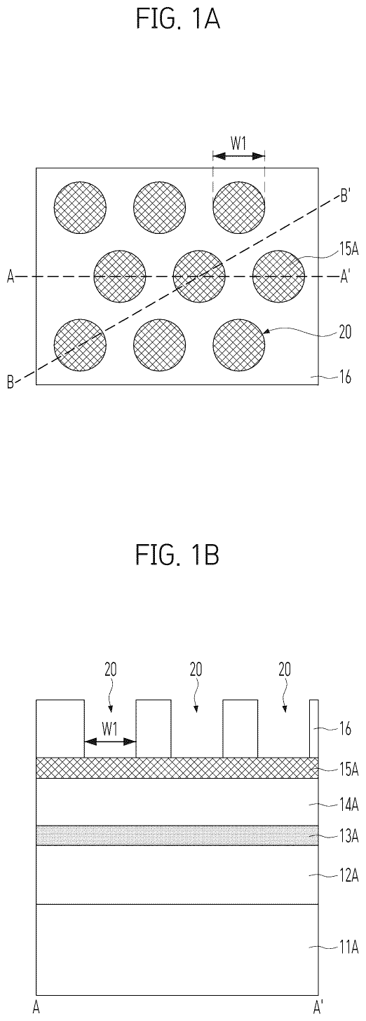

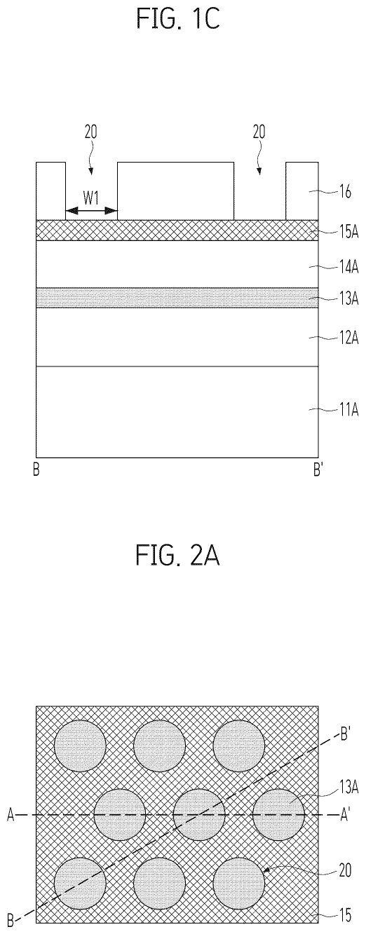

FIGS. 1A, 2A, 3A, 4A, 5A, 6A, 7A, 8A, 9A, 10A, 11A and 12A are plan views illustrating a method for forming a hole pattern in accordance with an embodiment of the present invention. FIGS. 1B, 2B, 3B, 4B, 5B, 6B, 7B, 8B, 9B, 10B, 11B and 12B are cross-sectional views taken along a line A-A′ shown in FIGS. 1A, 2A, 3A, 4A, 5A, 6A, 7A, 8A, 9A, 10A, 11A and 12A, respectively. FIGS. 1C, 2C, 3C, 4C, 5C, 6C, 7C, 8C, 9C, 10C, 11C and 12C are cross-sectional views taken along a line B-B′ shown in FIGS. 1A, 2A, 3A, 4A, 5A, 6A, 7A, 8A, 9A, 10A, 11A and 12A, respectively. To help understanding, the plan views and the cross-sectional views are separately presented, and for the sake of convenience in description, drawings of the same stage are presented and described together.

Referring to FIGS. 1A to 1C, a first hard mask layer 12A, a second hard mask layer 13A, a first sacrificial layer 14A, and a second sacrificial layer 15A may be sequentially formed over etch target layer 11A.The etch target layer 11A may be a substrate or a mold layer that is provided to form a hole pattern. For example, the etch target layer 11A may include silicon nitride. According to another embodiment of the present invention, the etch target layer 11A may include a carbon-based material. The carbon-based material as this term is used here refers to a carbon material or a material including carbon and some other material. For example, the carbon-based material may include carbon or Spin-On-Carbon (SOC).

The first and second hard mask layers 12A and 13A may be hard masks for etching the etch target layer 11A. The first and second hard mask layers 12A and 13A may include a material having an etch selectivity with respect to the etch target layer 11A. The first hard mask layer 12A and the second hard mask layer 13A may have different etch selectivities. For example, the first and second hard mask layers 12A and 13A may include a carbon or a silicon-based Spin-On-Hard mask (SOH), an oxide material, a combination of oxide materials, or any combination thereof. For example, the first and second hard mask layers 12A and 13A may include a stacked structure of a carbon-based hard mask and an oxide material. According to another embodiment of the present invention, the first and second hard mask layers 12A and 13A may include a stacked structure of a silicon-based hard mask and an oxide material. The silicon-based material as this term is used here refers to a silicon material or a material including silicon and some other material. According to another embodiment of the present invention, the second hard mask layer 13A may be omitted.

The first and second sacrificial layers 14A and 15A may be sacrificial layers for a Spacer Patterning Technology (SPT) process. The second sacrificial layer 15A may be a hard mask for etching the first sacrificial layer 14A. For example, the first sacrificial layer 14A may include a carbon-based material. For example, the carbon-based material may include carbon or SOC. The second sacrificial layer 15A may include a material having an etch selectivity with respect to the first sacrificial layer 14A. For example, the second sacrificial layer 15A may include silicon oxynitride (SiON).

Subsequently, a mask pattern 16 including a preliminary hole pattern 20 may be formed over the second sacrificial layer 15A. The line width W of the preliminary hole pattern defined by the mask pattern 16 may be formed by a single patterning of the DUV mask. The line width W1 of the preliminary hole pattern defined by the mask pattern 16 may have a wide line width that may be formed through a mask process using DUV (Deep Ultraviolet) that is performed once.

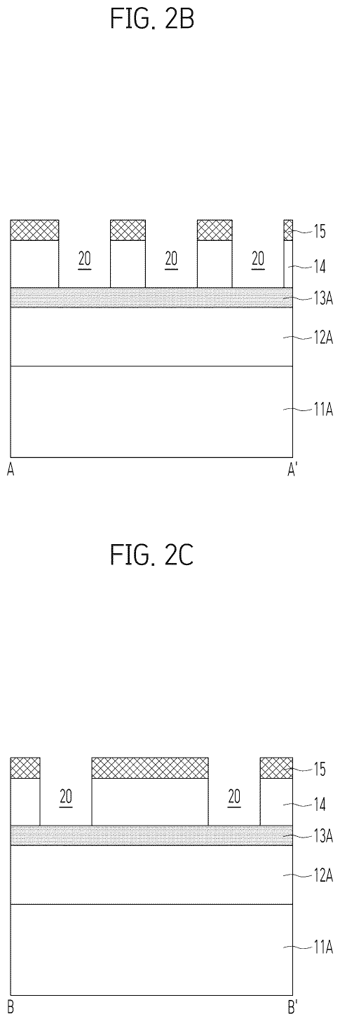

Referring to FIGS. 2A to 2C, first and second sacrificial patterns 14 and 15 including the preliminary hole pattern 20 may be formed. The first and second sacrificial patterns 14 and 15 may be formed by a series of processes of sequentially etching the second sacrificial layer 15A and the first sacrificial layer 14A by using the mask pattern 16 illustrated in FIGS. 1A to 1C.

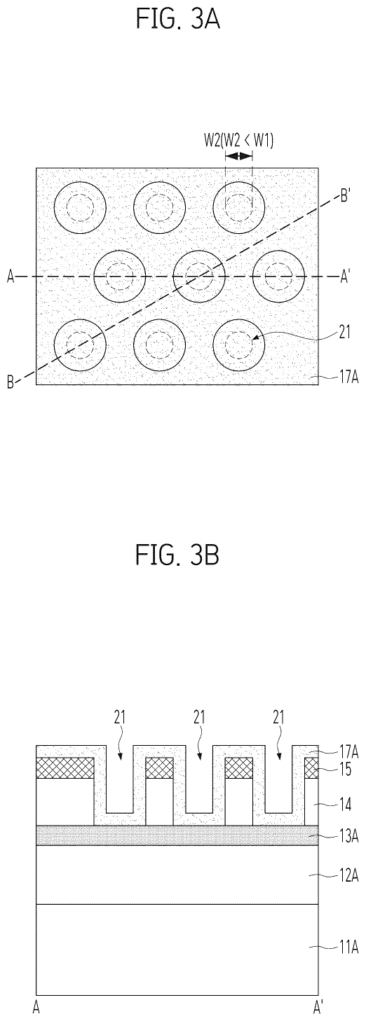

Referring to FIGS. 3A to 3C, the first sacrificial material layer 17A may be formed conformally along the entire structure including the first and second sacrificial patterns 14 and 15. The first hole pattern 21 may be formed by the first sacrificial material layer 17A. The line width W2 of the first hole pattern 21 may be smaller than the line width W1 of the preliminary hole pattern 20 (see FIG. 2A) (W2<W1).

The first sacrificial material layer 17A may include a material having an etch selectivity with respect to the second hard mask layer 13A and the first and second sacrificial patterns 14 and 15. The first sacrificial material layer 17A may include a dielectric material. The first sacrificial material layer 17A may conformally cover the entire structure including the first and second sacrificial patterns 14 and 15. For example, the first sacrificial material layer 17A is an ultra-low temperature oxide (ULTO) and may include SiO₂. Therefore, the shape and size of the hole pattern formed by the subsequent process may be maintained uniformly. According to another embodiment of the present invention, the first sacrificial material layer 17A may include an oxide or a nitride.

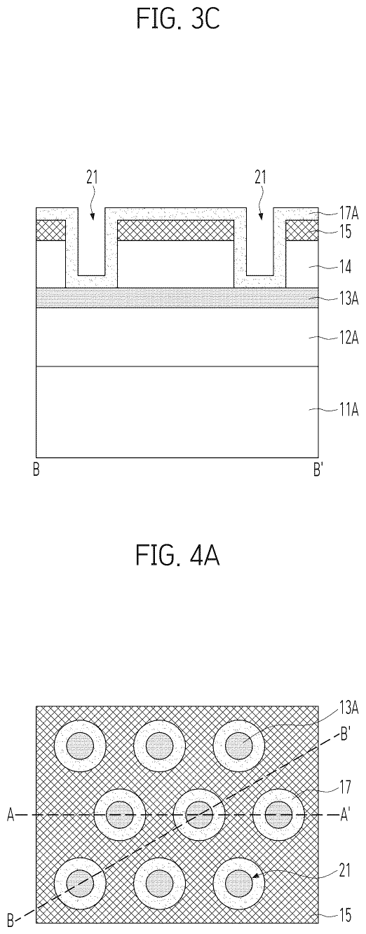

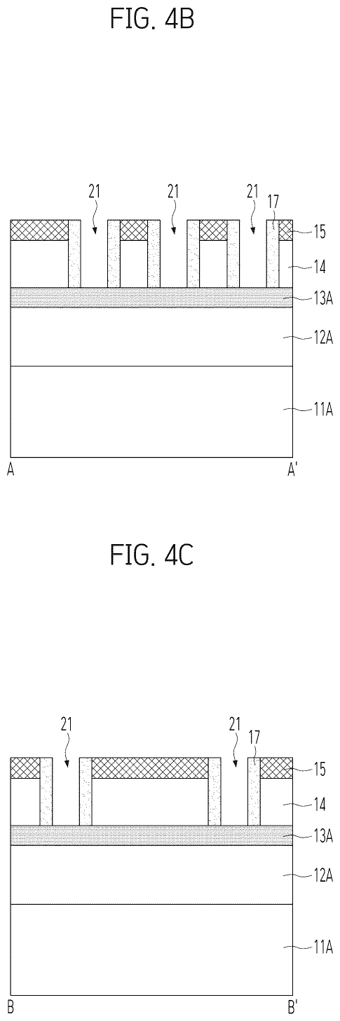

Referring to FIGS. 4A to 4C, a first sacrificial spacer 17 may be formed on the sidewalls of the first and second sacrificial patterns 14 and 15. To form the first sacrificial spacer 17, an etch-back process may be performed onto the first sacrificial material layer 17A (see FIG. 3B). The etch-back process may be performed to expose the second sacrificial pattern 15 and the second hard mask layer 13A.

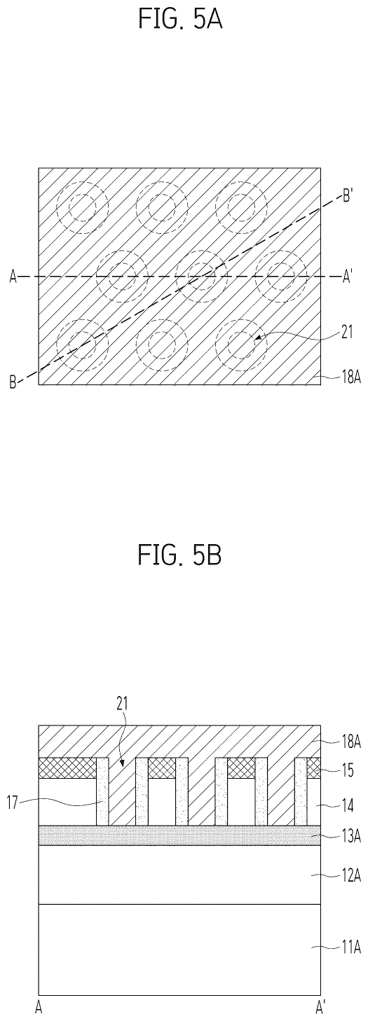

Referring to FIGS. 5A to 5C, a third sacrificial layer 18A may be formed to fill the first hole pattern 21 over the second hard mask layer 13A, the first sacrificial spacer 17, and the second sacrificial pattern 15. The third sacrificial layer 18A may be a material for maintaining the first hole pattern 21. The third sacrificial layer 18A may include a material having an etch selectivity with respect to the second sacrificial pattern 15 and the first sacrificial spacer 17. For example, the third sacrificial layer 18A may include a silicon-containing material. For example, the third sacrificial layer 18A may include polysilicon. According to another embodiment of the present invention, the third sacrificial layer 18A may include a carbon-based material. According to another embodiment of the present invention, the third sacrificial layer 18A may include a metal material, such as tungsten or titanium.

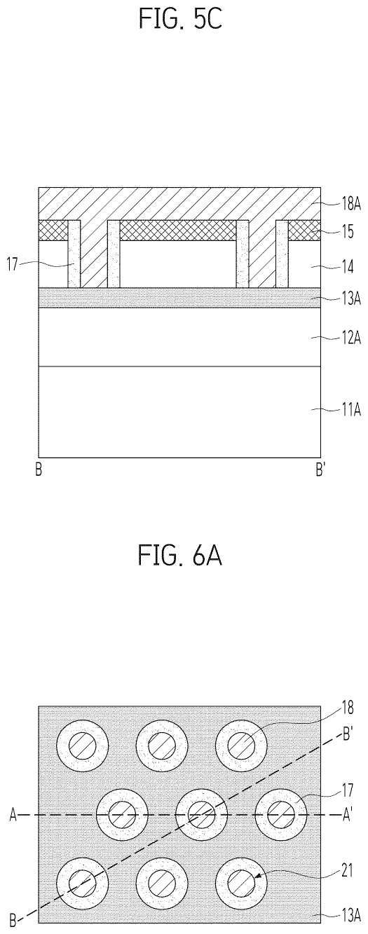

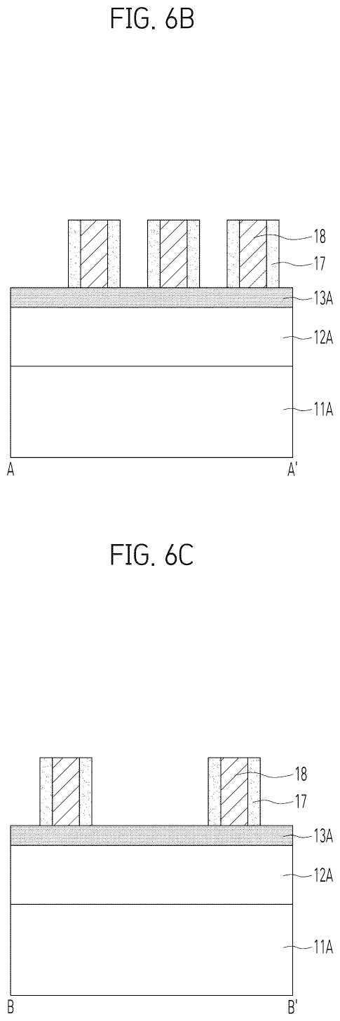

Referring to FIGS. 6A to 6C, a third sacrificial pattern 18 remaining only in the first hole pattern 21 may be formed. To form the third sacrificial pattern 18, the third sacrificial layer 18A (see FIG. 5B) over the first sacrificial spacer 17 and the second sacrificial pattern 15 may be removed. The third sacrificial layer 18A over the first sacrificial spacer 17 and the second sacrificial pattern 15 may be etched through an etch-back process.

Subsequently, the first and second sacrificial patterns 14 and 15 (see FIG. 5B) may be removed. As the first and second sacrificial patterns 14 and 15 are removed, the first sacrificial spacer 17 and the third sacrificial pattern 18 may remain over the second hard mask layer 13A.

The first sacrificial spacer 17 and the third sacrificial pattern 18 may provide a pillar pattern of the same line width as that of the preliminary hole pattern.

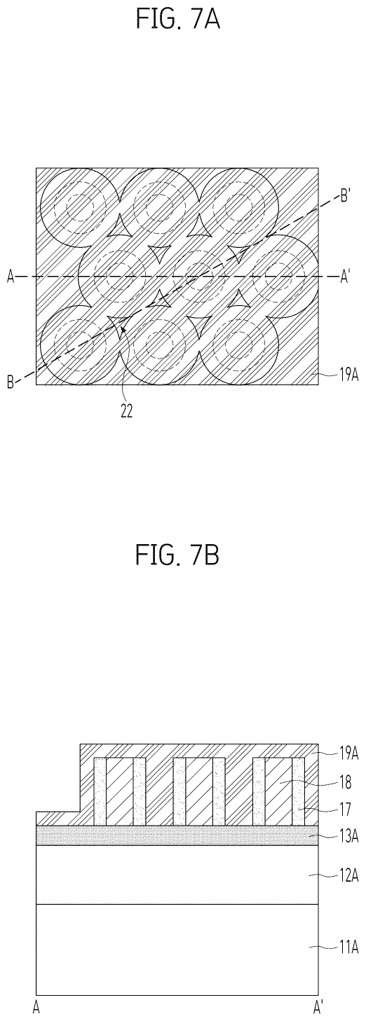

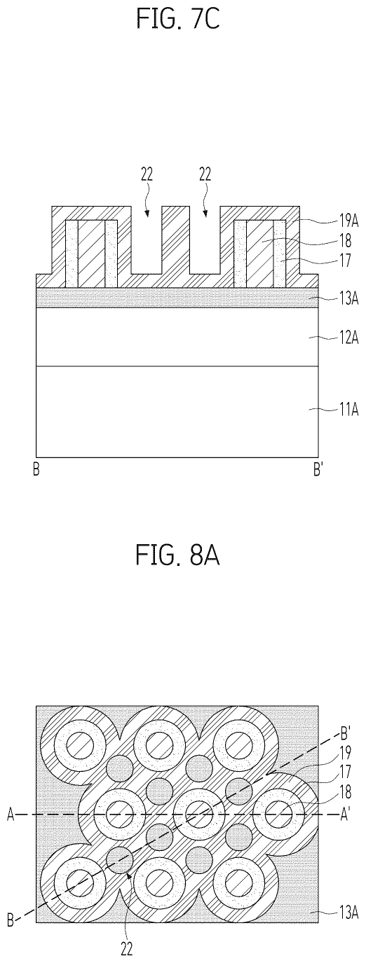

Referring to FIGS. 7A to 7C, a second sacrificial material layer 19A may be formed along the entire surface including the first sacrificial spacer 17 and the third sacrificial pattern 18.

The second sacrificial material layer 19A may include a material having an etch selectivity with respect to the third sacrificial pattern 18 and the second hard mask layer 13A. The second sacrificial material layer 19A may include the same material as that of the first sacrificial material layer 17A. The second sacrificial material layer 19A may include a dielectric material. The second sacrificial material layer 19A may conformally cover the entire structure including the pillar pattern. For example, the second sacrificial material layer 19A is an ultra-low temperature oxide (ULTO) and may include SiO₂. According to another embodiment of the present invention, the second sacrificial material layer 19A may include an oxide or a nitride.

The second sacrificial material layer 19A may be formed to have a thickness that gap-fills the spaces formed between the pillar patterns that are provided by the first sacrificial spacer 17 and the third sacrificial pattern 18. The second sacrificial material layer 19A may gap-fill between the pillar patterns that are adjacent to each other in the vertical and horizontal directions. A triangular space 22 may be formed between the pillar patterns that are adjacent to each other in a diagonal direction as shown in FIG. 7A.

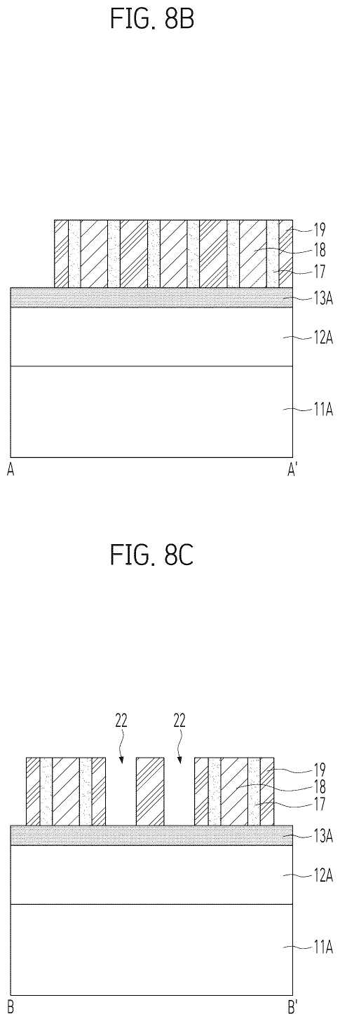

Referring to FIGS. 8A to 8C, a second sacrificial spacer 19 may be formed. To form the second sacrificial spacer 19, an etch-back process may be performed onto the second sacrificial material layer 19A (see FIG. 7B). The etch-back process may be performed to expose the top surfaces of the first sacrificial spacer 17 and the second hard mask layer 13A.

During the etch-back process for forming the second sacrificial spacer 19, a second hole pattern 22 may be formed between the pillar patterns. During the etch-back process, the exposed portion may be etched rapidly, and the relatively narrow portion may be less etched. As a result, the space 22 illustrated in FIG. 8A may be formed as a circular second hole pattern 22. The second hole pattern 22 may have a line width that is the same as or similar to the line width of the first hole pattern 21.

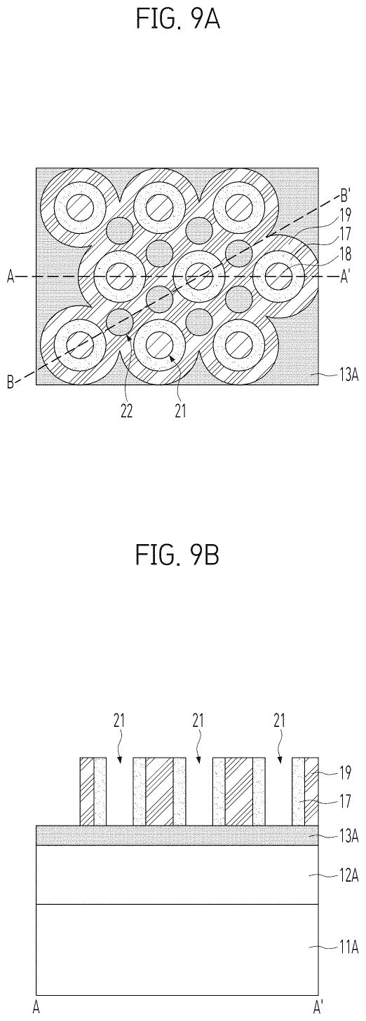

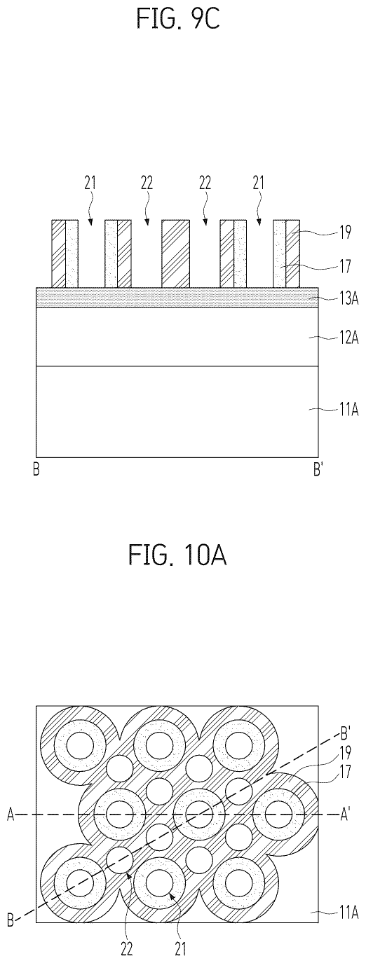

Referring now to FIGS. 9A to 9C, the third sacrificial pattern 18 (see FIG. 8B) may be removed leaving only the first and second sacrificial spacers 17 and 19 over the second hard mask layer 13A. The first and second sacrificial spacers 17 and 19 may define a first hole pattern 21 and a second hole pattern 22.

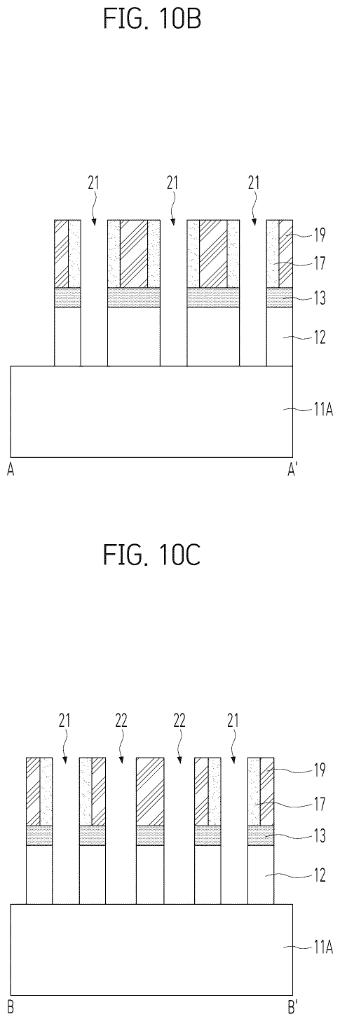

Referring to FIGS. 10A to 10C, first and second hard mask patterns 12 and 13 may be formed by extending the first hole pattern 21 and the second hole pattern 22. To form the first and second hard mask patterns 12 and 13, the first and second sacrificial spacers 17 and 19 may be used as etch barriers to sequentially etch the second hard mask layer 13A (see FIG. 9B) and the first hard mask layer 12A (see FIG. 9B).

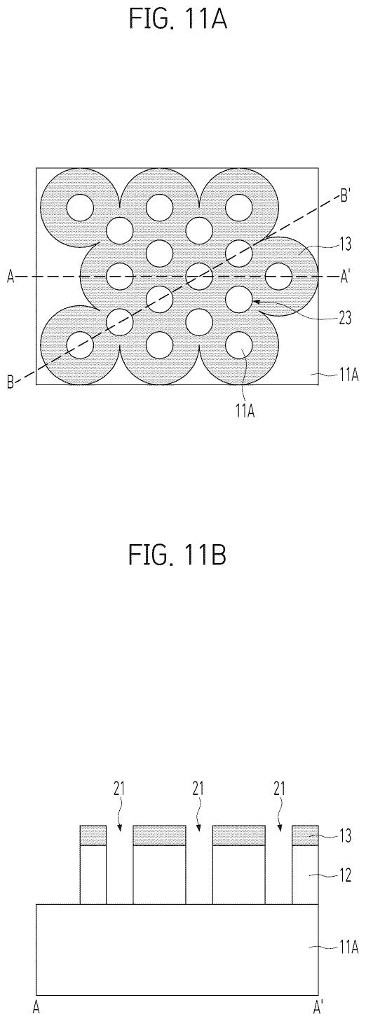

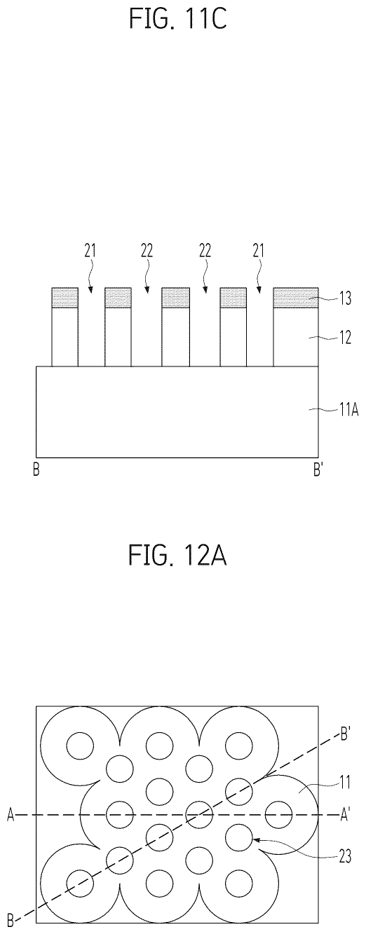

Referring to FIGS. 11A to 11C, the first and second sacrificial spacers 17 and 19 (see FIG. 9B) may be removed leaving only the first and second hard mask patterns 12 and 13.

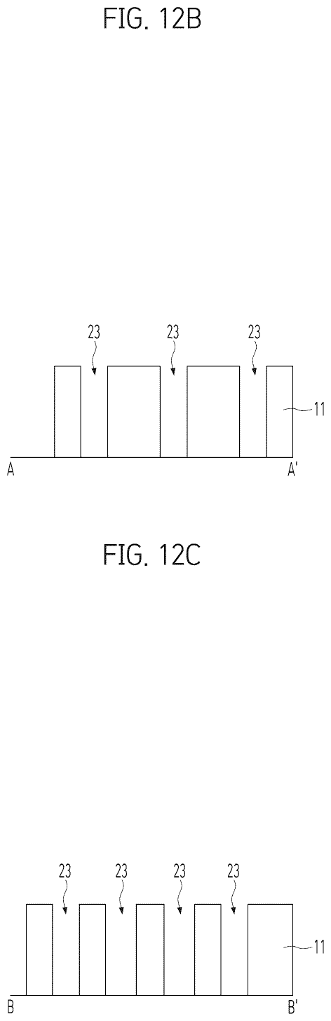

Referring to FIGS. 12A to 12C, the etch target layer 11A (see FIG. 11B) may be etched to form an etch pattern 11 defining a fine hole pattern 23.

As described above, according to an embodiment of the present invention, the fine hole pattern 23 may be formed via a DUV mask process that is performed once. As a comparative example, in the case of multi-patterning using two or more masks, misalignment or mis-registration with the lower layer may be caused due to the use of multiple masks. However, only one mask is used and the center of the additionally formed hole pattern does not move. This may be advantageous in terms of overlay management.

According to embodiments of the present invention, it may be possible to reduce production costs through reduction in the investment on the EUV equipment and thereby secure process margins by forming the line width of a hole pattern that can be formed only through EUV (Extreme Ultraviolet) patterning only through the DUV mask process. Also, since the line width of the initial hole pattern may be widened, the profile of the hole pattern and the uniformity between the hole patterns may be improved, and therefore, a pattern is formed that is advantageous for overlay alignment management. Also, the shape of the hole pattern and the line width of the hole pattern may be maintained uniformly.

It is noted, that the embodiments of the present invention are not limited only to the processes illustrated in FIGS. 1 to 12. For example, a finer hole pattern may be formed by repeatedly performing the spacer process illustrated in FIGS. 3 to 8. Also, although a positive-type spacer process is applied in embodiments of the present invention, the embodiments are not limited to this. In variations of the embodiments, or in another embodiment, a negative-type spacer process may be applied without departing from the scope of the present invention.

The fine hole patterns formed through the processes of FIGS. 1 to 12 may be applied, if needed, in the processes that require hole patterns during the fabrication of a semiconductor device (e.g., the processes for forming bit line contact holes, storage node contact holes, storage node holes, supporter holes, and the like).

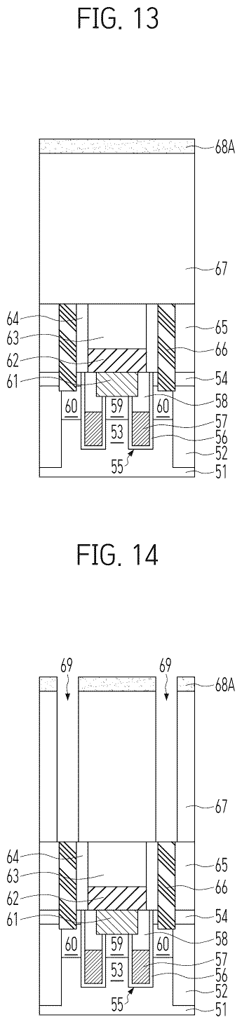

FIGS. 13 to 19 are cross-sectional views illustrating a method for fabricating a semiconductor device in accordance with an embodiment of the present invention.

Referring to FIGS. 13 to 19, the semiconductor device may include a buried gate structure BG and a bit line structure BL.

An isolation layer 52 defining an active region 53 may be formed over a substrate 51. A plurality of spaced apart active regions 53 may be defined by the isolation layer 52.

The substrate 51 may be formed of any suitable semiconductor material including, for example, a material containing silicon. For example, the substrate 51 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 51 may also include another semiconductor material, such as germanium. The substrate 51 may include a group-III/V semiconductor substrate, for example, a compound semiconductor substrate, such as GaAs. The substrate 51 may include a Silicon-On-Insulator (SOI) substrate.

A buried gate structure BG may be formed in the substrate 51. The buried gate structure BG may include a gate dielectric layer 56 formed on the surface of a gate trench 55, a gate electrode 57 formed over the gate dielectric layer 56 at a lower portion of the gate trench 55, and a gate capping layer 58 formed over the gate dielectric layer 56 and a top surface of the gate electrode 57 to fill the remaining upper portion of the gate trench 55.

For example, a gate trench 55 may be formed in the substrate 51 to a predetermined depth in a region defined by a hard mask layer 54 that is formed on the surface of the substrate 51. The bottom surface of the gate trench 55 may be disposed at a higher level than the bottom surface of the isolation layer 52. The gate trench 55 may have a shallower depth than the isolation layer 52. According to the illustrated embodiment of the present invention, the bottom portion of the gate trench 55 may have a flat surface. However, according to another embodiment of the present invention, the bottom portion of the gate trench 55 may have a curvature. According to another embodiment of the present invention, the isolation layer 52 in a direction in which the gate trench 55 extends may be etched to a predetermined depth to form a fin in the active region 53.

The gate dielectric layer 56 may be formed on the surface of the gate trench 55. The gate electrode 57 may be formed over the gate dielectric layer 56 to fill a lower portion of the gate trench 55. A gate capping layer (a sealing layer) 58 may be formed over the gate electrode 57 to fill the remaining upper portion of the gate trench 55.

The top surface of the gate capping layer 58 may be disposed at the same level as the top surface of the hard mask layer 54. The top surface of the gate electrode 57 may be disposed at a lower level than the top surface of the substrate 51. The gate electrode 57 may be formed of a low-resistance metal material. According to an embodiment, the gate electrode 57 may be formed by sequentially stacking titanium nitride and tungsten. According to another embodiment of the present invention, the gate electrode 57 may be formed of titanium nitride (TiN) only.

First and second impurity regions 59 and 60 may be formed in the substrate 51. The first and second impurity regions 59 and 60 may be referred to as ‘first and second source/drain regions.’ The first and second impurity regions 59 and 60 may be spaced apart from each other by a gate trench 55. Accordingly, the gate electrode 57 and the first and second impurity regions 59 and 60 may become a cell transistor. The cell transistor may improve a short channel effect by using the gate electrode 57 having a buried gate structure.

A bit line contact 61 coupled to the first impurity region 59 may be formed over the substrate 51. A bit line structure BL may be formed over the bit line contact 61. The bit line structure BL may be electrically connected to the first impurity region 59 of the substrate 51 through the bit line contact 61. The bit line structure BL may include a stacked structure of a bit line 62 and a bit line hard mask 63. The bit line structure BL may extend in one direction while covering the top surface of the bit line contact 61. The bit line 62 may include a metal material. The bit line hard mask 63 may include a dielectric material.

Bit line spacers 64 may be formed on both sides of the bit line structure BL. The bit line spacers 64 may include a dielectric material.

A storage node contact 66 may be formed between the neighboring bit line structures BL. The storage node contact 66 may be coupled to the second impurity region 60. The storage node contact 66 may have a pillar shape. The storage node contact 66 may include a conductive material. For example, the conductive material may include a semiconductor material or a metal material. For example, the semiconductor material may include polysilicon. For example, the metal material may include tungsten (W). According to another embodiment of the present invention, the storage node contact 66 may include a stacked structure of a semiconductor material and a metal material. According to another embodiment of the present invention, the storage node contact 66 may include a stacked structure of a semiconductor material, an ohmic contact layer, and a metal material.

The storage node contacts 66 may be separated from each other by a plug isolation layer 65. The plug isolation layer 65 may include a dielectric material.

Subsequently, a mold layer 67 and a supporter layer 68A may be sequentially stacked over the entire structure including the storage node contact 66, the plug isolation layer 65 and the bit line hard mask 63. The mold layer 67 may be used to form a space for forming the lower electrode 69, and it may include a dielectric material. The supporter layer 68A may be used to support the lower electrode 69, and it may include a dielectric material.

According to another embodiment of the present invention, an inter-layer dielectric layer, and a landing pad electrically connecting the lower electrode 69 and the storage node contact 66 through the inter-layer dielectric layer may be further included between the mold layer 67 and the storage node contact 66. According to another embodiment of the present invention, an etch stop layer may be further included between the mold layer and the storage node contact 66.

According to another embodiment of the present invention, the stacked structure of the mold layer 67 and the supporter layer 68A may be repeatedly applied, if needed.

Referring to FIG. 14, an SN hole 69 penetrating the mold layer 67 and the supporter layer 68A may be formed. The storage node contact 66 may be exposed by the SN hole 69.

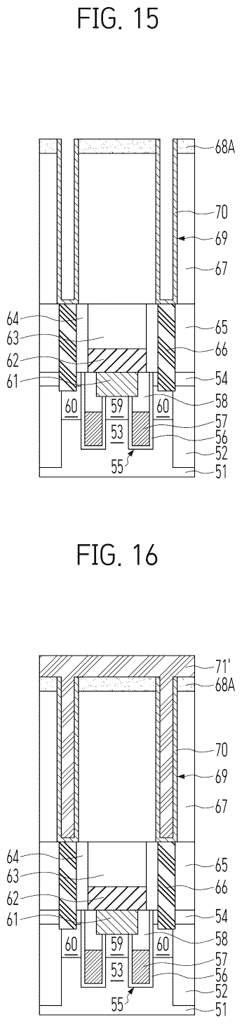

Referring to FIG. 15, a first lower electrode 70 may be formed conformally along the inner wall and bottom surface of the SN hole 69. The first lower electrode 70 may have a cylindrical shape. The first lower electrode 70 may include a metal nitride. For example, the first lower electrode 70 may include titanium nitride. According to another embodiment of the present invention, the metal nitride may include a low-resistance metal nitride. For example, the low-resistance metal nitride may include one of tantalum nitride (TaN), niobium nitride (NbN), molybdenum nitride (MoN), and tungsten nitride (WN), but the embodiments of the present invention are not limited thereto.

Referring to FIG. 16, a conductive layer 71′ may be formed over the first lower electrode 70 to gap-fill the SN hole 69. The conductive layer 71′ may include a material for forming a lower electrode structure together with the first lower electrode 70. For example, the conductive layer 71′ may include polysilicon, but the embodiments of the present invention are not limited thereto.

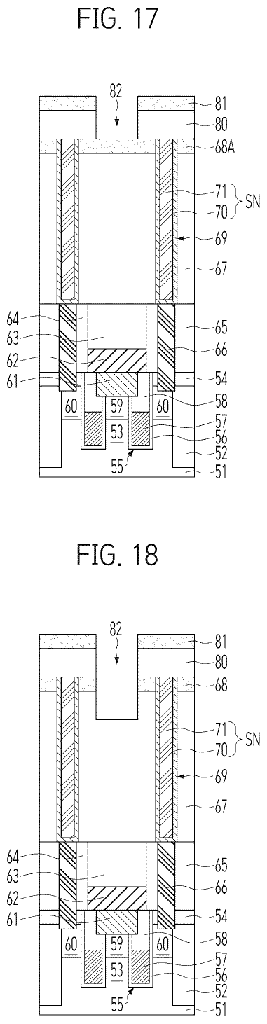

Referring to FIG. 17, a lower electrode structure SN may be formed to gap-fill the SN hole 69. To form the lower electrode structure SN, an etch-back process may be performed onto the conductive layer 71′ (see FIG. 16), to expose the supporter layer 68A. The etched conductive layer 71′ may be referred to as a ‘second lower electrode 71’. The lower electrode structure SN may include a stacked structure of the first lower electrode 70 and the second lower electrode 71. The lower electrode structure SN may include a first lower electrode 70 of a cylindrical shape and a second lower electrode 71 of a pillar shape formed inside the cylindrical space defined by the first lower electrode 70. According to another embodiment of the present invention, the lower electrode structure SN may include a cylindrical shape or a pillar shape that is formed of a single layer.

Subsequently, first and second hard mask patterns 80 and 81 defining a fine hole pattern 82 may be formed over the lower electrode structure SN and the supporter layer 68A. The first and second hard mask patterns 80 and 81 may correspond to the first and second hard mask patterns 12 and 13 illustrated in FIGS. 11A to 11C. The supporter layer 68A and the mold layer 67 may correspond to the etch target layer 11A illustrated in FIGS. 11A to 11C. The fine hole pattern 82 may correspond to the first and second hole patterns 21 and 22 illustrated in FIGS. 11A to 11C. The first and second hard mask patterns 80 and 81 and the fine hole pattern 82 may be formed through the same method as the hole pattern forming method of FIGS. 1 to 11.

According to another embodiment of the present invention, the first and second hard mask patterns 80 and 81 may be formed over the conductive layer 71′ of FIG. 16.

Referring to FIG. 18, a supporter 68 may be formed. To form the supporter 68, the supporter layer 68A (see FIG. 17) may be etched by using the first and second hard mask patterns 80 and 81. A supporter hole 82 may be included between the neighboring supporters 68. The supporter hole 82 may correspond to the fine hole pattern 23 illustrated in FIGS. 12A to 12C. The supporter hole 82 may have a line width which is narrower than the gap between the neighboring lower electrode structures SN. According to another embodiment of the present invention, the supporter hole 82 may have a line width which is the same as or greater than the gap between the neighboring lower electrode structures SN.

Subsequently, the first and second hard mask patterns 80 and 81 may be removed.

According to another embodiment of the present invention, when the first and second hard mask patterns 80 and 81 are formed over the conductive layer 71′ of FIG. 16, after the supporter hole 82 is formed, the first and second hard mask patterns 80 and 81 may be removed and then an etch-back process for forming the second lower electrode 71 may be performed.

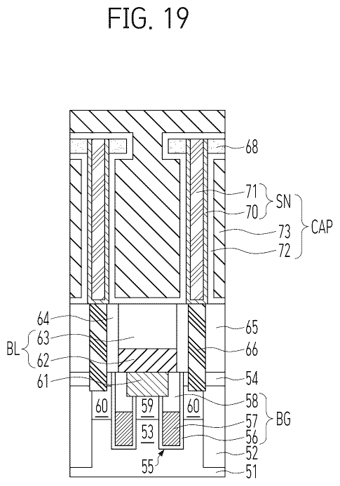

Referring to FIG. 19, the mold layer 67 (see FIG. 18) may be removed. The mold layer 67 may be removed through a dip-out process by using the supporter hole 82 (see FIG. 18) that is etched to form the supporter 68.

As the mold layer 67 is removed, the lower electrode structure SN and the supporter 68 may remain over the storage node contact 66.

Subsequently, a capacitor CAP in which the dielectric layer 72 and the upper electrode 73 are sequentially stacked over the lower electrode structure SN may be formed.

The dielectric layer 72 may cover the entire structure including the lower electrode structure SN. The dielectric layer 72 may include a single layered structure, a multi-layered structure, or a laminated structure. The dielectric layer 72 may have a doping structure or an inter-mixing structure. The dielectric layer 72 may include a high-k material. The dielectric layer 72 may have a higher dielectric constant than silicon oxide (SiO₂). Silicon oxide may have a dielectric constant of approximately 3.9, and the dielectric layer 72 may include a material having a dielectric constant of approximately 4 or more. The high-k material may have a dielectric constant of approximately 20 or more. The high-k material 72 may include hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃).

The upper electrode 73 may cover the dielectric layer 72. The upper electrode 73 may include, for example, a silicon-containing material, a germanium-containing material, a metal-containing material, or a combination thereof. The upper electrode 73 may include, for example, a metal, a metal nitride, a metal carbide, a conductive metal oxide, or a combination thereof. For example, the upper electrode 73 may include titanium (Ti), titanium nitride (TiN), tantalum nitride (TaN), titanium carbon nitride (TiCN), tantalum carbon nitride (TaCN), tungsten (W), tungsten nitride (WN), ruthenium (Ru), iridium (Ir), ruthenium oxide (RuO₂), iridium oxide (IrO₂), or a combination thereof. For example, the upper electrode 73 may include a silicon layer (Si layer), a germanium layer (Ge layer), a silicon germanium layer (SiGe layer), or a combination thereof.

According to embodiments of the present invention, it is possible to decrease process difficulty and secure process margins by forming a fine hole pattern while applying a DUV mask.

While the present invention has been described with respect to specific embodiments, it will be apparent to those skilled in the art that various changes and modifications may be made without departing from the spirit and scope of the invention as defined in the following claims. Furthermore, the embodiments may be combined to from additional embodiments.

What is claimed is:

1. A method for forming a hole pattern, the method comprising:
forming a hard mask layer over an etch target layer;
forming a first sacrificial pattern including a preliminary hole pattern over the hard mask layer;
forming a first sacrificial spacer on an inner wall of the first sacrificial pattern;
forming a second sacrificial pattern to gap-fill between the first sacrificial spacers;
removing the first sacrificial pattern;
forming second sacrificial spacers on both sidewalls of a pillar pattern which is formed of the first sacrificial spacer and the second sacrificial pattern;
removing the second sacrificial pattern;
forming a hard mask pattern by using the first and second sacrificial spacers as an etch barrier and etching the hard mask layer; and
forming an etch pattern including a hole pattern by using the hard mask pattern as an etch barrier and etching the etch target layer.

2. The method of claim 1, wherein the hard mask layer includes a carbon-or a silicon-based Spin-On-Hard mask (SOH), an oxide material, a combination of oxide materials, or any combination thereof.

3. The method of claim 1, wherein the hard mask layer includes a stacked structure of a first hard mask layer and a second hard mask layer.

4. The method of claim 3, wherein the first hard mask layer includes a carbon-or a silicon-based Spin-On-Hard mask (SOH), and the second hard mask layer includes an oxide material.

5. The method of claim 1, wherein the forming of the first sacrificial spacer includes:
forming a first sacrificial layer that conformally covers an entire structure including the first sacrificial pattern; and
performing an etch-back process onto the first sacrificial layer.

6. The method of claim 1, wherein the first sacrificial spacer includes a dielectric material.

7. The method of claim 1, wherein the first sacrificial spacer includes an oxide or a nitride.

8. The method of claim 1, wherein the first sacrificial spacer is an ultra-low temperature oxide (ULTO) and includes SiO₂.

9. The method of claim 1, wherein the first and second sacrificial spacers include a same material.

10. The method of claim 1, wherein the forming of the second sacrificial spacer includes:
forming a second sacrificial layer that conformally covers an entire structure including the pillar pattern; and
performing an etch-back process onto the second sacrificial layer.

11. The method of claim 1, wherein the second sacrificial spacer is an ultra-low temperature oxide (ULTO) and includes SiO₂.

12. The method of claim 1, wherein the second sacrificial spacer has a thickness of gap-filling between the pillar patterns that are vertically and horizontally adjacent to each other.

13. The method of claim 1, wherein the second sacrificial pattern includes a material having an etch selectivity with respect to the first sacrificial pattern and the first sacrificial spacer.

14. The method of claim 1, wherein the first sacrificial pattern includes a carbon-containing material.

15. The method of claim 1, wherein the second sacrificial pattern includes polysilicon.

16. The method of claim 1, wherein the second sacrificial pattern includes a carbon-containing material or a metal material.

17. The method of claim 1, wherein the preliminary hole pattern is patterned through a DUV (Deep Ultraviolet) mask process that is performed once.

18. A method for fabricating a semiconductor device, the method comprising:
forming a mold layer and a supporter layer that include storage node holes over a substrate;
forming a lower electrode gap-filling the storage node holes and coupled to the substrate;
forming a hard mask layer over the lower electrode and the supporter layer;
forming a first sacrificial pattern including a preliminary hole pattern over the hard mask layer;
forming a first sacrificial spacer on an inner wall of the first sacrificial pattern;
forming a second sacrificial pattern to gap-fill between the first sacrificial spacers;
removing the first sacrificial pattern;
forming second sacrificial spacers on both sidewalls of a pillar pattern which is formed of the first sacrificial spacer and the second sacrificial pattern;
removing the second sacrificial pattern;
forming a hard mask pattern including a hole pattern by using the first and second sacrificial spacers as an etch barrier and etching the hard mask layer; and
forming a supporter including a supporter hole by using the hard mask pattern as an etch barrier and etching the supporter layer.

19. The method of claim 18, further comprising:
after forming the supporter,
removing the mold layer;
forming a dielectric layer that covers an entire structure including the lower electrode; and
forming an upper electrode over the dielectric layer.

20. The method of claim 19, wherein removing the mold layer is performed through a deep-out process.

21. The method of claim 18, wherein the hard mask layer includes a carbon-or silicon-based Spin-On-Hard mask (SOH) or a combination of oxide materials.

22. The method of claim 18, wherein the hard mask layer includes a stacked structure of a first hard mask layer and a second hard mask layer.

23. The method of claim 22, wherein the first hard mask layer includes a carbon-or a silicon-based Spin-On-Hard mask (SOH), and the second hard mask layer includes an oxide material.

24. The method of claim 18, wherein the first and second sacrificial spacers include an ultra-low temperature oxide (ULTO).

25. The method of claim 18, wherein the first sacrificial pattern includes a carbon-containing material.

26. The method of claim 18, wherein the second sacrificial pattern includes polysilicon.
